(19) United States
(12) Patent Application Publication
(10) Pub. No.: US 2025/0359468 A1
(43) Pub. Date: Nov. 20, 2025

(54) DISPLAY DEVICE AND METHOD OF MANUFACTURING THE SAME

(71) Applicant: Samsung Display Co., LTD., Yongin-si (KR)

(72) Inventor: Kyu Ho JUNG, Yongin-si (KR)

(73) Assignee: Samsung Display Co., LTD., Yongin-si (KR)

(21) Appl. No.: 19/019,905

(22) Filed: Jan. 14, 2025

(30) Foreign Application Priority Data
May 20, 2024 (KR) 10-2024-0065280

(51) Int. Cl. H10K 59/80; H10K 59/12; H10K 59/127; H10K 77/10

(52) U.S. Cl. CPC H10K 59/873; H10K 59/1201; H10K 59/127; H10K 59/8793; H10K 77/111

(57) ABSTRACT

A display device is provided. The display device includes a display panel including a main area, a bending area, and a pad area; a display driver and a circuit board disposed on the pad area of the display panel a resin layer disposed on the display panel and covering the display driver and the circuit board; and a polarizing film disposed on the resin layer, wherein the resin layer is formed in portions overlapping the main area, the bending area, and the pad area.

### CROSS-REFERENCE TO RELATED APPLICATION(S)

This application claims priority to and benefits of Korean Patent Application No. 10-2024-0065280 under 35 U.S.C. §119 filed on May 20, 2024 in the Korean Intellectual Property Office, the entire contents of which are incorporated herein by reference.

### BACKGROUND

### 1. Technical Field

The disclosure relates to a display device and a method of manufacturing the display device.

### 2. Description of the Related Art

As the information society advances, the demand for display devices to show images is increasing in various forms. Display devices may include flat-panel displays such as liquid crystal displays (LCDs), field emission displays (FEDs), and light-emitting displays.

A display device may include a display area that displays an image and a non-display area around the display area, for example, an area arranged to surround the display area. Recently, to enhance the immersive experience of the display area and improve the aesthetics of the display device, the width of the non-display area has been gradually decreasing.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

Aspects of the disclosure provide a display device and a method of manufacturing the display device, which can enhance the mechanical strength of a display panel, pad driving unit, and circuit board and offer ease of manufacturing.

However, aspects of the disclosure are not restricted to those set forth herein. The above and other aspects of the disclosure will become more apparent to one of ordinary skill in the art to which the disclosure pertains by referencing the detailed description of the disclosure given below.

According to an aspect of the disclosure, a display device may include a display panel including a main area, a bending area, and a pad area; a display driver and a circuit board disposed on the pad area of the display panel, a resin layer disposed on the display panel and covering the display driver and the circuit board; and a polarizing film disposed on the resin layer, wherein the resin layer is formed in portions overlapping the main area, the bending area, and the pad area.

In an embodiment, in a portion overlapping the main area, the resin layer may contact the display panel and the polarizing film, and the resin layer completely fills a space between the display panel and the polarizing film in a direction perpendicular to the display panel.

In an embodiment, the resin layer may contact the display driver and the circuit board, and completely covers the display driver.

In an embodiment, the resin layer may include an organic material.

In an embodiment, the main area may include a display area and a non-display area surrounding the display area, and a shape of the resin layer overlapping the non-display area differs from a shape of the resin layer overlapping the pad area in a cross-section.

In an embodiment, the resin layer may include at least one concave portion and at least one convex portion, which have different thicknesses, in a portion overlapping the non-display area in the cross-section.

In an embodiment, the concave portion may be a portion that may include a minimum thickness of the resin layer relative to the display panel, and the convex portion is a portion that may include a maximum thickness of the resin layer relative to the display panel.

In an embodiment, in a portion overlapping the pad area, the resin layer may include a slope with a thickness that gradually decreases in a direction toward an outermost surface of the display panel.

In an embodiment, the slope of the resin layer may overlap the display driver and the circuit board in a direction perpendicular to the display panel.

In an embodiment, the resin layer may include a uniform thickness in a portion overlapping the display area, with a process tolerance of about 50 μm.

In an embodiment, the display panel may include a first substrate, which overlaps the main area and the pad area, and may include an opening that overlaps the bending area, and has a rigid material, and a second substrate, which is disposed on the first substrate and has a flexible material, the first substrate may include a first sub-substrate, which overlaps the main area, and a second sub-substrate, which overlaps the pad area, and the first sub-substrate and the second sub-substrate may be spaced apart with the opening between the first sub-substrate and the second sub-substrate.

In an embodiment, the first sub-substrate may include a first surface facing the second substrate, a second surface opposite to the first surface, and an edge surface connecting the second surface and an outermost surface of the display panel in a portion overlapping the non-display area, and an inclination angle formed by the second surface and the edge surface may be an obtuse angle.

In an embodiment, the edge surface may overlap the resin layer in a direction perpendicular to the display panel.

In an embodiment, the first sub-substrate may further include a first side surface connected to the first surface and facing the bending area, and a second side surface connected to the first side surface and the second surface and facing the bending area, the first side surface of the first sub-substrate and a lower surface of the second substrate form an undercut in a direction toward the bending area, and in a direction perpendicular to the display panel, the resin layer may overlap the undercut.

In an embodiment, the second sub-substrate may include a third side surface facing the bending area and opposite to the first side surface of the first sub-substrate, the third side surface and the second substrate form the undercut in a direction toward the bending area; and in a direction perpendicular to the display panel, the resin layer may overlap the third side surface.

According to an aspect of the disclosure, a method of manufacturing a display device may include preparing a display panel including a main area, a bending area, and a pad area, and a display driver and circuit board attached to the pad area of the display panel; attaching a resin application jig, which entirely surrounds the main area on a plane, to an outermost surface of the display panel; applying a resin layer over the main area, bending area, and pad area of the display panel and curing the resin layer with an ultraviolet (UV) lamp; and removing the resin application jig.

In an embodiment, in a forming of the resin layer, the resin layer may be formed in portions overlapping the main area, bending area, and the pad area.

In an embodiment, in the forming the resin layer, a flow of the resin layer overlapping a non-display area may be controlled by the resin application jig.

In an embodiment, in the attaching of the resin application jig, the resin application jig may not overlap the circuit board.

In an embodiment, in forming of the resin layer, the resin layer overlapping a non-display area may include at least one concave portion and at least one convex portion, and the resin layer overlapping the pad area may include a slope with a thickness decreasing toward the outermost surface of the display panel.

In an embodiment, an electronic device comprising: a display device comprising: a display panel including a main area, a bending area, and a pad area; a display driver and a circuit board disposed on the pad area of the display panel; a resin layer disposed on the display panel and covering the display driver and the circuit board; and a polarizing film disposed on the resin layer, wherein the resin layer is formed in portions overlapping the main area, the bending area, and the pad area.

According to the aforementioned and other embodiments of the disclosure, by providing a resin layer that entirely covers display drivers and circuit boards on a display panel, the mechanical strength of the display panel, display unit, and circuit board can be improved.

By way of example, as the resin layer is applied to the entire surface of the display panel after forming a resin application jig surrounding the perimeter of the display panel, a method of manufacturing a display device with ease of manufacturing can be provided.

It should be noted that the effects of the disclosure are not limited to those described above, and other effects of the disclosure will be apparent from the following description.

### BRIEF DESCRIPTION OF THE DRAWINGS

The above and other aspects and features of the disclosure will become more apparent by describing in detail embodiments thereof with reference to the attached drawings, in which:

FIG. 1 is a schematic plan view illustrating a display device according to an embodiment;

FIG. 2 is a schematic cross-sectional view taken along line Y1-Y1′ of FIG. 1;

FIG. 3 is a schematic cross-sectional view illustrating a display panel of FIG. 2 in a bent state;

FIG. 4 is a schematic cross-sectional view of a display area included in the display device;

FIG. 5 is an enlarged schematic cross-sectional view of the display device overlapping a first non-emission area in FIG. 2;

FIG. 6 is an enlarged schematic cross-sectional view of the display device overlapping a pad area in FIG. 2;

FIG. 7 is a schematic cross-sectional view taken along line X1-X1′ of FIG. 1;

FIG. 8 is a schematic cross-sectional view taken along line X3-X3′ of FIG. 1;

FIG. 9 is a flowchart for explaining a method of manufacturing a resin layer according to an embodiment;

FIG. 10 is a schematic perspective view illustrating step S1001 of FIG. 9;

FIGS. 11 and 12 are schematic plan views illustrating step S1001 of FIG. 9;

FIGS. 13 and 14 are schematic perspective views illustrating step S1003 of FIG. 9;

FIG. 15 is a schematic perspective view illustrating step S1005 of FIG. 9; and

FIG. 16 is a schematic perspective view illustrating step S1007 of FIG. 9.

FIG. 17 is a block diagram of an electronic device according to an embodiment of the disclosure.

FIG. 18 is a schematic diagram of an electronic device according to various embodiments of the disclosure.

### DETAILED DESCRIPTION OF THE EMBODIMENTS

In the following description, for the purposes of explanation, numerous details are set forth in order to provide a thorough understanding of various embodiments or implementations of the disclosure. As used herein “embodiments” and “implementations” are interchangeable words that are non-limiting examples of devices or methods disclosed herein. It is apparent, however, that various embodiments may be practiced without these given details or with one or more equivalent arrangements. Here, various embodiments do not have to be exclusive nor limit the disclosure. For example, given shapes, configurations, and characteristics of an embodiment may be used or implemented in an embodiment.

Unless otherwise specified, the illustrated embodiments are to be understood as providing features of the disclosure. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the disclosure.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a given process order may be performed differently from the described order. For example, two consecutively described processes may be performed substantially at the same time or performed in an order opposite to the described order. Also, like reference numerals and/or reference characters denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements.

Further, the X-axis, the Y-axis, and the Z-axis are not limited to three axes of a rectangular coordinate system, such as the x, y, and z axes, and may be interpreted in a broader sense. For example, the X-axis, the Y-axis, and the Z-axis may be perpendicular to one another, or may represent different directions that are not perpendicular to one another.

As used herein, the singular forms, “a,” “an,” and “the” are intended to include the plural forms as well, unless the context clearly indicates otherwise.

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

For the purposes of this disclosure, “at least one of A and B” may be construed as A only, B only, or any combination of A and B. Also, “at least one of X, Y, and Z” and “at least one selected from the group consisting of X, Y, and Z” may be construed as X only, Y only, Z only, or any combination of two or more of X, Y, and Z. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (for example, as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (for example, rotated 90 degrees or at other orientations), and, as such, the spatially relative descriptors used herein interpreted accordingly.

The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art.

The terms “face” and “facing” mean that a first element may directly or indirectly oppose a second element. In a case in which a third element intervenes between the first and second element, the first and second element may be understood as being indirectly opposed to one another, although still facing each other.

When an element is described as ‘not overlapping’ or ‘to not overlap’ another element, this may include that the elements are spaced apart from each other, offset from each other, or set aside from each other or any other suitable term as would be appreciated and understood by those of ordinary skill in the art.

The terminology used herein is for the purpose of describing embodiments and is not intended to be limiting. Moreover, the terms “comprises,” “comprising,” “includes,” and/or “including,” “has,” “have,” and/or “having,” and variations thereof when used in this specification, specify the presence of stated features, integers, steps, operations, elements, components, and/or groups thereof, but do not preclude the presence or addition of one or more other features, integers, steps, operations, elements, components, and/or groups thereof.

It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As customary in the field, embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (for example, microcode) to perform various functions discussed herein and may optionally be driven by firmware and/or software. It is also contemplated that each block, unit, and/or module may be implemented by dedicated hardware, or as a combination of dedicated hardware to perform some functions and a processor (for example, one or more programmed microprocessors and associated circuitry) to perform other functions. Also, each block, unit, and/or module of embodiments may be physically separated into two or more interacting and discrete blocks, units, and/or modules without departing from the scope of the disclosure. Further, the blocks, units, and/or modules of embodiments may be physically combined into more complex blocks, units, and/or modules without departing from the scope of the disclosure.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

Unless otherwise defined or implied herein, all terms (including technical and scientific terms) used herein have the same meaning as commonly understood by one of ordinary skill in the art to which the disclosure pertains. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

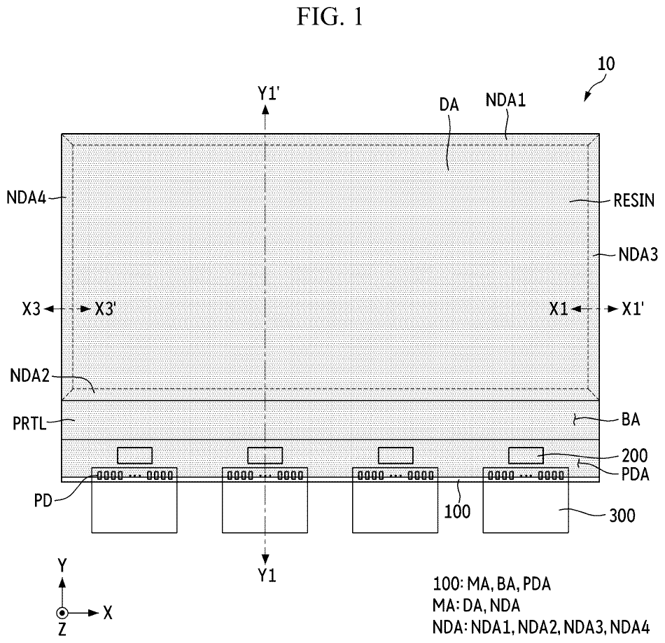

FIG. 1 is a schematic plan view illustrating a display device according to an embodiment.

Referring to FIG. 1, a display device 10, which is a device for displaying moving or still images, may be used as a display screen for various products such as mobile phones, smart phones, tablet personal computers (PCs), smart watches, watch phones, portable communication terminals, electronic notepads, electronic books, portable multimedia players (PMPs), navigation devices, and Ultra Mobile PCs (UMPCs), as well as televisions, laptops, monitors, billboards, and Internet of Things (IoT) devices.

The display device 10 may be an emissive display device such as an organic light-emitting display device using organic light-emitting diodes (OLEDs), a quantum dot light-emitting display device including a quantum dot light-emitting layer, an inorganic light-emitting display device including inorganic semiconductors, or a micro-or nano-light-emitting diode (micro-or nano-LED) display device. The display device 10 will hereinafter be described as being an organic light-emitting display device, but the disclosure is not limited thereto.

The display device 10 may be used as an electronic device. An electronic device including the display device 10 may include the display screen of portable electronic devices such as a mobile phone, a smart phone, a tablet PC, a smart watch, a watch phone, a mobile communications terminal, an electronic notebook, an electronic book, a portable multimedia player (PMP), a navigation device and a ultra mobile PC (UMPC), a television, a notebook, a monitor, a billboard and the Internet of Things (IoT). Those listed-above are merely as examples, and the display device 10 may be employed in other electronic devices as well.

The display device 10 may include a display panel 100, display driving units (or drivers) 200, circuit boards 300, a bending protection layer PRTL, and a resin layer RESIN.

The display panel 100 may be formed in the form of a rectangular plane having long sides in a first direction (or an X-axis direction) and short sides in a second direction (or a Y-axis direction) intersecting the first direction. The corners where the long sides in the first direction and the short sides in the second direction meet may be formed at right angles or may be rounded to have curvature. The planar shape of the display panel 100 is not particularly limited, and the display panel 100 may be formed in various other shapes, such as another substantially polygonal shape, a substantially circular shape, or a substantially elliptical shape.

The first direction (or the X-axis direction) and the second direction (or the Y-axis direction) intersect each other as horizontal directions. For example, the first direction (or the X-axis direction) and the second direction (or the Y-axis direction) may be orthogonal to each other. By way of example, a third direction (or a Z-axis direction) may intersect the first direction (or the X-axis direction) and the second direction (or the Y-axis direction), and may be a vertical direction orthogonal to both the first and second directions. Sides in the first, second, and third directions indicated by the arrows in the drawings may each be referred to as one side or a side or a first side, and the opposite sides may each be referred to as the other side or another side or a second side.

The display panel 100 may be formed flat, but the disclosure is not limited thereto. As an example, the display panel 100 may be formed with curved sections at its left and right ends, having a constant or varying curvature. By way of example, the display panel 100 may be formed to be flexible, such as bendable, foldable, or rollable.

The display panel 100 may include a main area MA, a bending area BA, and a pad area PDA. The main area MA may include a display area DA, which displays an image, and a non-display area NDA, which surrounds or may be adjacent to the display area DA.

The display area DA may occupy most of the display panel 100 and may be located (or disposed) at the center of the display panel 100. The display area DA is an area that displays an image.

The non-display area NDA may be located adjacent to the display area DA. The non-display area NDA may be the area outside the display area DA and may surround or may be adjacent to the display area DA.

In an embodiment, the non-display area NDA may include a first non-display area NDA1, a second non-display area NDA2, a third non-display area NDA3, and a fourth non-display area NDA4. The first non-display area NDA1 may be located on one side or a side of the display area DA in the second direction (or the Y-axis direction), and the second non-display area NDA2 may be located on the other side of the display area DA in the second direction (or the Y-axis direction). The first and second non-display areas NDA1 and NDA2 may face each other across the display area DA. By way of example, the third non-display area NDA3 may be located on one side or a side of the display area DA in the first direction (or the X-axis direction), and the fourth non-display area NDA4 may be located on the other side of the display area DA in the first direction (or the X-axis direction). The third and fourth non-display areas NDA3 and NDA4 may face each other across the display area DA.

In other words, on a plane, the first non-display area NDA1 may be located at the upper end of the display panel 100, the third non-display area NDA3 may be located at the right end of the display panel 100, and the fourth non-display area NDA4 may be located at the left end of the display panel 100. The second non-display area NDA2 may be located at the lower end of the main area MA, facing the bending area BA.

The bending area BA may be located between the main area MA and the pad area PDA in the second direction (or the Y-axis direction). The bending area BA may extend in the first direction (or the X-axis direction). The bending area BA of the display panel 100 may bend in the third direction (or the Z-axis direction) toward the bottom. The bending phenomenon of the display panel 100 will be described later.

The bending protection layer PRTL may be located in a portion overlapping the bending area BA. The bending protection layer PRTL may be positioned on the display panel 100 in the portion overlapping the bending area BA. The bending protection layer PRTL is illustrated as overlapping the bending area BA, but the disclosure is not limited thereto. The bending protection layer PRTL may also overlap a portion of the second non-display area NDA2 of the main area MA and a portion of the pad area PDA.

The bending protection layer PRTL may protect multiple wirings located in the portion overlapping the bending area BA from bending stress in case that the display panel 100 is bent. By way of example, the bending protection layer PRTL may protect various wirings from moisture and oxygen permeability.

The pad area PDA may be located in the lower region of the display panel 100. The pad area PDA may be the area where display pads PD and display driving units 200 are located. The display pads PD may be positioned close to the lower edge of the display panel 100.

The display driving units 200 may be positioned to overlap the pad area PDA. The display driving units 200 may generate data voltages, power supply voltages, scan timing signals, etc. The display driving units 200 may output data voltages, power supply voltages, scan timing signals, etc. The display driving units 200 may be attached to the display panel 100 by a chip-on-glass (COG) method, but the disclosure is not limited thereto. As an example, in an embodiment, the display driving units 200 may be attached to the circuit boards 300 by a chip-on-plastic (COP) method.

The circuit boards 300 may be positioned on the display pads PD. The circuit boards 300 may be attached to the display pads PD using conductive adhesive members such as anisotropic conductive films and anisotropic conductive adhesives. The circuit boards 300 may be electrically connected to the signal wirings of the display panel 100. The circuit boards 300 may be flexible films such as flexible printed circuit boards (FPCBs) or chip-on-films (COFs).

The resin layer RESIN may be positioned on the display panel 100. The resin layer RESIN may be located in the portions overlapping the main area MA, the bending area BA, and the pad area PDA. The resin layer RESIN may be integral with in the portions overlapping the main area MA, the bending area BA, and the pad area PDA. In other words, the resin layer RESIN overlapping the main area MA, the bending area BA, and the pad area PDA may not have distinct boundaries.

The resin layer RESIN may cover the bending protection layer PRTL, the display driving units 200, and the circuit boards 300 on the display panel 100. The resin layer RESIN may contact the display panel 100, the bending protection layer PRTL, the display driving units 200, and the circuit boards 300.

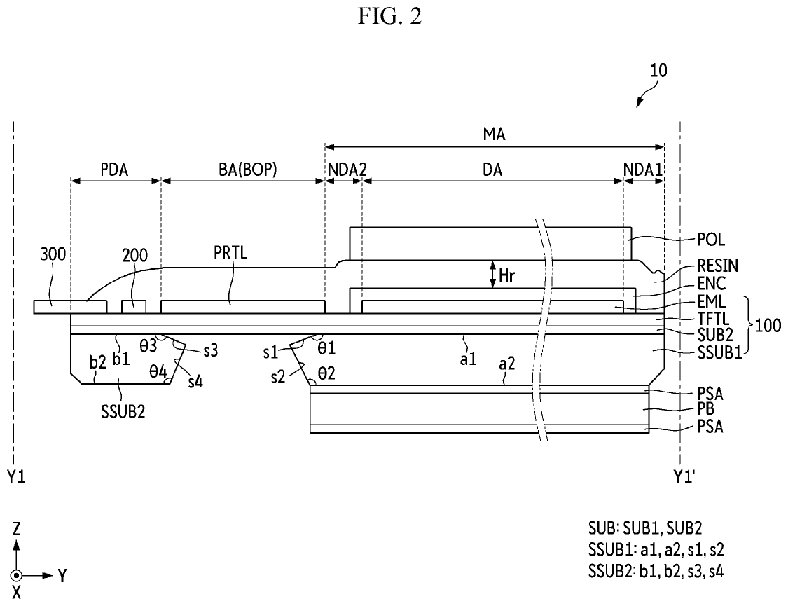

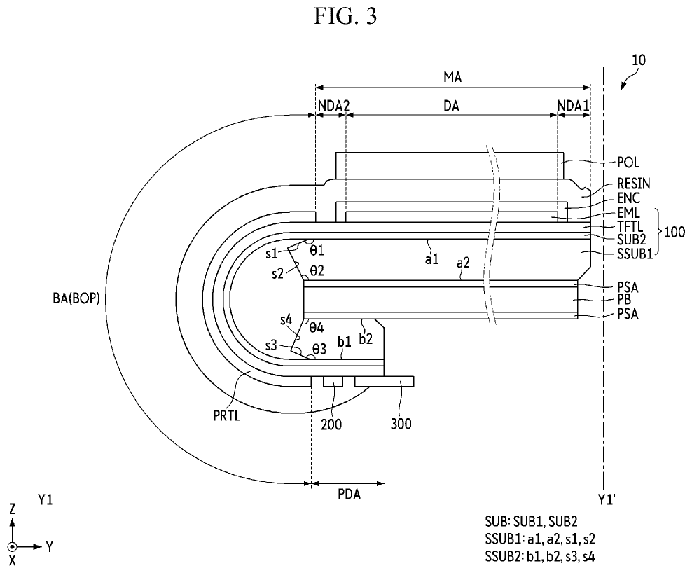

FIG. 2 is a schematic cross-sectional view taken along line Y1-Yl′ of FIG. 1. FIG. 3 is a schematic cross-sectional view illustrating the display panel of FIG. 2 in a bent state.

Referring to FIGS. 2 and 3, in cross-section, the display device 10 may include the display panel 100, the display driving units 200, the circuit boards 300, the bending protection layer PRTL, and the resin layer RESIN, in addition to a polarizing film POL and a panel bottom cover PB. The display panel 100 may include a substrate SUB, a thin-film transistor layer TFTL, a light-emitting element layer EML, and an encapsulation layer ENC.

In an embodiment, the substrate SUB may include a first substrate SUB1 and a second substrate SUB2.

In an embodiment, the first substrate SUB1 may be formed of a rigid material. For example, the first substrate SUB1 may be formed of glass. The first substrate SUB1 may be formed of ultra-thin glass (UTG) with a thickness of about 500 μm or less. The first substrate SUB1 may include an opening BOP, which exposes the second substrate SUB2. The opening BOP may be located overlapping the bending area BA.

The first substrate SUB1 may include a first sub-substrate SSUB1 and a second sub-substrate SSUB2. The first and second sub-substrates SSUB1 and SSUB2 may be spaced apart in the second direction (or the Y-axis direction) with the opening BOP in between. During the manufacture of the display device 10, the first and second sub-substrates SSUB1 and SSUB2 may be initially formed integrally as a single unit, and a portion of the first substrate SUB1 overlapping the bending area BA may be removed through an etching process, thereby obtaining the first and second sub-substrates SSUB1 and SSUB2 as illustrated in FIG. 2.

In an embodiment, the first sub-substrate SSUB1 may include a first surface a1, a second surface a2, a first side s1, and a second side s2.

The first surface al of the first sub-substrate SSUB 1 may face the second substrate SUB2, and the second surface a2 may face opposite the first surface a1. By way of example, the first side s1 may be positioned toward the bending area BA and connected to the first surface al, and the second side s2 may be positioned toward the bending area BA and connected to the second surface a2. The first and second surfaces a1 and a2 may be connected by the first and second sides s1 and s2.

In an embodiment, the first and second sides s1 and s2 of the first sub-substrate SSUB1 may be inclined surfaces. By way of example, a first angle θ1 formed by the first surface a1 and the first side s1, and a second angle θ2 formed by the second surface a2 and the second side s2, may be obtuse angles. By way of example, the second substrate SUB2 and the first side s1 of the first sub-substrate SSUB1 may form an undercut in a direction toward the bending area BA. This undercut may be formed by removing a portion of the first sub-substrate SSUB1 overlapping the bending area BA during the manufacture of the display device 10 through an etching process.

In an embodiment, the second sub-substrate SSUB2 may include a first surface b1, a second surface b2, a first side s3, and a second side s4.

The first surface b1 of the second sub-substrate SSUB2 may face the second substrate SUB2, and the second surface b2 may face opposite the first surface b1. By way of example, the first side s3 may be positioned toward the bending area BA and connected to the first surface b1, and the second side s4 may be positioned toward the bending area BA and connected to the second surface b2. The first and second surfaces b1 and b2 may be connected by the first and second sides s3 and s4.

In an embodiment, the first side s3 and the second side s4 of the second sub-substrate SSUB2 may be inclined surfaces. By way of example, a first angle θ3 formed by the first surface b1 and the first side s3, and a second angle θ4 formed by the second surface b2 and the second side s4, may be obtuse angles. By way of example, the second substrate SUB2 and the first side s3 of the second sub-substrate SSUB2 may form an undercut in a direction toward the bending area BA. This undercut may be formed by removing a portion of the second sub-substrate SSUB2 overlapping the bending area BA during the manufacture of the display device 10 through an etching process.

In an embodiment, the panel bottom cover PB may be located on the second surface a2 of the first sub-substrate SSUB1. The panel bottom cover PB may be attached to the first substrate SUB1 of the display panel 100 through an adhesive member PSA. The adhesive member PSA may be a pressure-sensitive adhesive.

The panel bottom cover PB may include at least one of a light-shielding member for absorbing light incident from the outside, a cushioning member for absorbing shocks from the outside, and a heat-dissipating member for efficiently dissipating heat from the display panel 100.

In an embodiment, the second substrate SUB2 may be formed of a flexible material. The second substrate SUB2 may be formed of a polymer resin with a lower thickness than the first substrate SUB1. For example, the second substrate SUB2 may be formed of an organic material such as an acrylic resin, epoxy resin, phenolic resin, polyamide resin, or polyimide resin.

The second substrate SUB2 may have a thickness of about 20 μm or less. In an embodiment, the second substrate SUB2 may have a multilayer structure.

In an embodiment, the thin-film transistor layer TFTL may be located on the second substrate SUB2. The thin-film transistor layer TFTL may be located in the portions overlapping the main area MA, the bending area BA, and the pad area PDA. The thin-film transistor layer TFTL may overlap the first and second sides s1 and s2 of the first sub-substrate SSUB1 and the first and second sides s3 and s4 of the second sub-substrate SSUB2 in the third direction (or the Z-axis direction). By way of example, the thin-film transistor layer TFTL may overlap in the third direction (or the Z-axis direction) with the undercut formed by the first side s1 of the first sub-substrate SSUB1 and the second substrate SUB2, and with the undercut formed by the first side s3 of the second sub-substrate SSUB2 and the second substrate SUB2.

In an embodiment, the light-emitting element layer EML may be located on the thin-film transistor layer TFTL. The light-emitting element layer EML may be positioned in the portion overlapping the display area DA of the main area MA. The structure of the light-emitting element layer EML will be described later in detail.

In an embodiment, the encapsulation layer ENC may be located on the light-emitting element layer EML. The encapsulation layer ENC may be positioned in the portion overlapping the main area MA. The encapsulation layer ENC may protect the light-emitting element layer EML from external moisture and oxygen. By way of example, the encapsulation layer ENC may protect the light-emitting element layer EML from damage caused by external foreign substances. The structure of the encapsulation layer ENC will be described later in detail.

In an embodiment, the bending protection layer PRTL may be located on the display panel 100. The bending protection layer PRTL may be positioned on the thin-film transistor layer TFTL in the portion overlapping the bending area BA. The bending protection layer PRTL may be positioned in a portion overlapping the opening BOP formed by the first sub-substrate SSUB1 and the second sub-substrate SSUB2.

The bending protection layer PRTL may overlap in the third direction (or the Z-axis direction) with the first and second sides s1 and s2 of the first sub-substrate SSUB1, and with the first and second sides s3 and s4 of the second sub-substrate SSUB2. By way of example, the bending protection layer PRTL may overlap in the third direction (or the Z-axis direction) with the undercut formed by the first side s1 of the first sub-substrate SSUB1 and the second substrate SUB2, and with the undercut formed by the first side s3 of the second sub-substrate SSUB2 and the second substrate SUB2.

The bending protection layer PRTL may be formed of an organic material such as an acrylic resin, epoxy resin, phenolic resin, polyamide resin, or polyimide resin.

In an embodiment, the display driving units 200 and the circuit boards 300 may be located on the display panel 100. The display driving units 200 and the circuit boards 300 may be positioned on the thin-film transistor layer TFTL in the portion overlapping the pad area PDA. The display driving units 200 and the circuit boards 300 may overlap the second sub-substrate SSUB2 in the third direction (or the Z-axis direction).

In an embodiment, the resin layer RESIN may be located on the display panel 100. The resin layer RESIN may be positioned on the encapsulation layer ENC, the bending protection layer PRTL, the display driving units 200, and the circuit boards 300, in the portions overlapping the main area MA, the bending area BA, and the pad area PDA. The resin layer RESIN may fill all the space between the display panel 100 and the polarizing film POL in the third direction (or the Z-axis direction).

The resin layer RESIN may contact the display panel 100 and the bending protection layer PRTL and extend to contact the display driving units 200 and the circuit boards 300. In cross-section, the resin layer RESIN may cover the encapsulation layer ENC, the bending protection layer PRTL, the display driving units 200, and the circuit boards 300. In cross-section, the resin layer RESIN may be integrally formed in the portions overlapping the main area MA, the bending area BA, and the pad area PDA.

The resin layer RESIN may overlap in the third direction (or the Z-axis direction) with the first and second sides s1 and s2 of the first sub-substrate SSUB1, and the first and second sides s3 and s4 of the second sub-substrate SSUB2. By way of example, the resin layer RESIN may overlap in the third direction (or the Z-axis direction) with the undercut formed by the first side s1 of the first sub-substrate SSUB1 and the second substrate SUB2, and with the undercut formed by the first side s3 of the second sub-substrate SSUB2 and the second substrate SUB2.

The resin layer RESIN may include an organic material. For example, the resin layer RESIN may include a silicone resin, acrylic resin, silicone-acrylic resin, urethane-acrylic resin, epoxy resin, phenolic resin, polyamide resin, or polyimide resin.

In an embodiment, the resin layer RESIN may have a uniform thickness Hr in the portion overlapping the display area DA. Therefore, the resin layer RESIN can minimize the loss of light from the display panel 100 in the portion overlapping the display area DA. However, the thickness Hr of the resin layer RESIN in the portion overlapping the display area DA may include a process tolerance of about 50 um.

In an embodiment, in cross-section, the shape of the resin layer RESIN in a portion overlapping the first non-display area NDA1 may differ from the shape of the resin layer RESIN in the portion overlapping the pad area PDA. This will be described later in detail.

In an embodiment, the polarizing film POL may be located on the resin layer RESIN. The polarizing film POL may be positioned in the portion overlapping the main area MA.

The polarizing film POL may reduce external light reflection. The polarizing film POL may include a first base member, a linear polarizer, a quarter-wave plate (for example, a λ/4 plate), and a second base member. The first base member, the phase retardation film, the linear polarizer, and the second base member of the polarizing film POL may be sequentially stacked on the display panel 100.

Referring to FIG. 3, the portion of the display panel 100 overlapping the bending area BA may be bent toward the other side in the third direction (or the Z-axis direction). In case that the portion of the display panel 100 is bent, the pad area PDA may overlap the main area MA in the third direction (or the Z-axis direction). In other words, in case that the display panel 100 is bent, the first and second sub-substrates SSUB1 and SSUB2 may overlap each other in the third direction (or the Z-axis direction). In case that the display panel 100 is bent, the second sub-substrate SSUB2 may be attached to the panel bottom cover PB by the adhesive member PSA.

By covering the display panel 100, the resin layer RESIN can improve the mechanical strength of the display panel 100. By way of example, by covering the display driving units 200 and the circuit boards 300, the resin layer RESIN can improve the mechanical strength of the display driving units 200 and the circuit boards 300. By way of example, in case that the display panel 100 is bent, the resin layer RESIN can enhance the mechanical strength of the display panel 100, the display driving units 200, and the circuit boards 300 against bending stress.

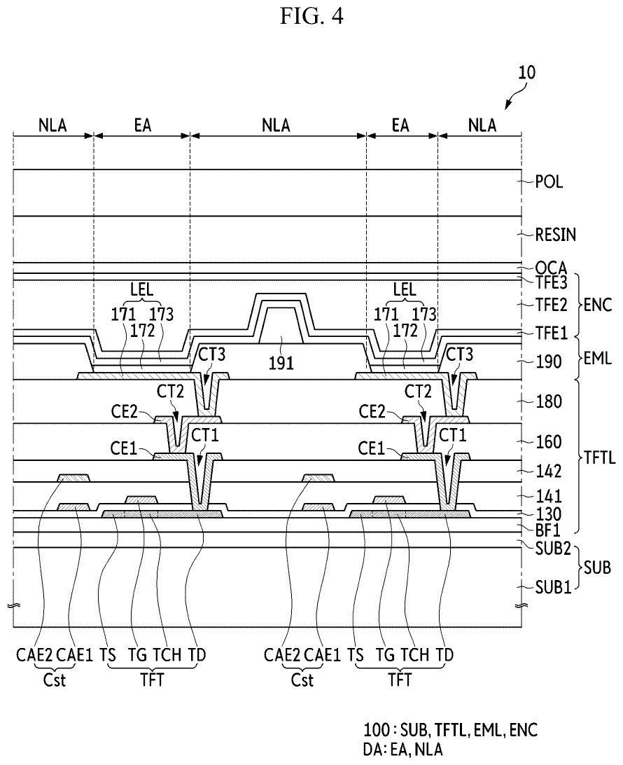

FIG. 4 is a schematic cross-sectional view of the display area included in the display device according to an embodiment.

Referring to FIG. 4, the display device 10 may include the display panel 100, the resin layer RESIN, and the polarizing film POL in the portion overlapping the display area DA. The display panel 100 may include the substrate SUB, the thin-film transistor layer TFTL, the light-emitting element layer EML, and the encapsulation layer ENC. The substrate SUB has already been described with reference to FIG. 2, and thus, a detailed description thereof may be omitted.

The thin-film transistor layer TFTL may be located on the substrate SUB. The thin-film transistor layer TFTL may include a first buffer layer BF1, thin-film transistors TFT, a gate insulating layer 130, a first insulating layer 141, capacitors Cst, a second insulating layer 142, first connection electrodes CE1, a first via layer 160, second connection electrodes CE2, and a second via layer 180.

The first buffer layer BF1 may be located on the substrate SUB. The first buffer layer BF1 may be formed of an inorganic material such as a silicon nitride layer, a silicon oxynitride layer, a silicon oxide layer, a titanium oxide layer, and an aluminum oxide layer. As an example, the first buffer layer BF1 may be formed as a multilayer film in which multiple layers of silicon nitride, silicon oxynitride, silicon oxide, titanium oxide, and aluminum oxide may be alternately stacked with each other.

The active layers of the thin-film transistors TFT, which include channel regions TCH, source regions TS, and drain regions TD, may be located on the first buffer layer BF1. The active layers may be formed of a material such as polycrystalline silicon, monocrystalline silicon, low-temperature polycrystalline silicon, amorphous silicon, or an oxide semiconductor material. If the active layers include polycrystalline silicon or an oxide semiconductor material, the source regions TS and the drain regions TD in the active layers may be conductive regions doped with ions or impurities to have conductivity.

The gate insulating layer 130 may be located on the active layers of the thin-film transistors TFT. The gate insulating layer 130 may be formed of an inorganic material, such as a silicon nitride layer, a silicon oxynitride layer, a silicon oxide layer, a titanium oxide layer, or an aluminum oxide layer.

Gate electrodes TG of the transistors TFT and first capacitor electrodes CAE1 of the capacitors Cst may be located on the gate insulating layer 130. The gate electrodes TG may overlap the channel regions TCH in the third direction (or the Z-axis direction).

The gate electrodes TG may be formed of a single layer or a multilayer of a material such as molybdenum (Mo), aluminum (Al), chromium (Cr), gold (Au), titanium (Ti), nickel (Ni), neodymium (Nd), copper (Cu), or an alloy thereof. The first capacitor electrodes CAE1 may be formed of a same material as the gate electrodes TG.

The first insulating layer 141 may be located on the gate electrodes TG and the first capacitor electrodes CAE1. The first insulating layer 141 may be formed of an inorganic material, such as a silicon nitride layer, a silicon oxynitride layer, a silicon oxide layer, a titanium oxide layer, or an aluminum oxide layer. The first insulating layer 141 may include inorganic films.

Second capacitor electrodes CAE2 of the capacitors Cst may be located on the first insulating layer 141. The second capacitor electrodes CAE2 may overlap the first capacitor electrodes CAE1 in the third direction (or the Z-axis direction). The capacitors Cst may be formed by inorganic insulating dielectric layers positioned between the first capacitor electrodes CAE1 and the second capacitor electrodes CAE2. The second capacitor electrodes CAE2 may be formed of a single layer or a multilayer of a material such as Mo, Al, Cr, Au, Ti, Ni, Nd, Cu, or an alloy thereof.

The second insulating layer 142 may be located on the second capacitor electrodes CAE2. The second insulating layer 142 may be formed of an inorganic material, such as a silicon nitride layer, a silicon oxynitride layer, a silicon oxide layer, a titanium oxide layer, or an aluminum oxide layer. The second insulating layer 142 may include inorganic films.

The first connection electrodes CE1 may be located on the second insulating layer 142. The first connection electrodes CE1 may be connected to the drain regions TD through first contact holes CT1 that penetrate the gate insulating layer 130, the first insulating layer 141, and the second insulating layer 142.

The first connection electrodes CE1 may be formed of a single layer or a multilayer of a material such as Mo, Al, Cr, Au, Ti, Ni, Nd, Cu, or an alloy thereof.

The first via layer 160 may be located on first connection electrodes CE1. The first via layer 160 may planarize the step differences caused by the thin-film transistors TFT.

The first via layer 160 may be formed of an organic material, such as an acrylic resin, epoxy resin, phenolic resin, polyamide resin, or polyimide resin.

The second connection electrodes CE2 may be located on the first via layer 160. The second connection electrodes CE2 may be connected to the first connection electrodes CE1 through second contact holes CT2 that penetrate the first via layer 160.

The second connection electrodes CE2 may be formed of a single layer or a multilayer of a material such as Mo, Al, Cr, Au, Ti, Ni, Nd, Cu, or an alloy thereof.

The second via layer 180 may be located on the second connection electrodes CE2. The second via layer 180 may be formed of an organic material, such as an acrylic resin, epoxy resin, phenolic resin, polyamide resin, or polyimide resin.

In an embodiment, the light-emitting element layer EML may be located on the thin-film transistor layer TFTL. The light-emitting element layer EML may include light-emitting elements LEL, which overlap emission areas EA, and a pixel-defining layer 190, which overlaps a non-emission area NLA. The emission areas EA and the non-emission areas NLA may be separated by the pixel-defining layer 190.

Each of the light-emitting elements LEL may include an anode electrode 171, a light-emitting layer 172, and a cathode electrode 173. Each of the emission areas EA may represent a region where the anode electrode 171, the light-emitting layer 172, and the cathode electrode 173 may be sequentially stacked, allowing holes from the anode electrode 171 and electrons from the cathode electrode 173 to combine in the light-emitting layer 172 and emit light.

The anode electrodes 171 may be formed on the second via layer 180. The anode electrodes 171 may be connected to the second connection electrodes CE2 through third contact holes CT3 that penetrate the second via layer 180.

The anode electrodes 171 may be formed of a single layer of Mo, Ti, Cu, or Al, or may be formed of a stacked structure of titanium/aluminum/titanium (Ti/Al/Ti) or indium tin oxide/aluminum/indium tin oxide (ITO/Al/ITO), a silver (Ag)-palladium (Pd)-copper (Cu) (APC) alloy, or a stacked structure of APC/ITO to increase reflectivity.

The pixel-defining layer 190 may be located on the second via layer 180. The pixel-defining layer 190 may define the emission areas EA. The pixel-defining layer 190 may be formed to expose the anode electrodes 171 in portions overlapping the emission areas EA. In other words, the pixel-defining layer 190 may be formed to cover the edges of the anode electrodes 171. The pixel-defining layer 190 may be located in the third contact holes CT3. For example, the third contact holes CT3 may be filled by the pixel-defining layer 190.

The pixel-defining layer 190 may be formed of an organic material, such as an acrylic resin, epoxy resin, phenolic resin, polyamide resin, or polyimide resin.

Spacers 191 may be located on the pixel-defining layer 190. The spacers 191 may support a mask during the manufacture of the light-emitting layers 172.

The spacers 191 may be formed of an organic material, such as acrylic resin, epoxy resin, phenolic resin, polyamide resin, or polyimide resin.

The light-emitting layers 172 may be located on the anode electrodes 171. The light-emitting layers 172 may include an organic material and emit light of a selectable color. The light-emitting layers 172 may emit light of different colors depending on the organic material included therein.

The cathode electrode 173 may be formed on the light-emitting layers 172. The cathode electrode 173 may be a common layer formed over both the emission areas EA and the non-emission area NLA.

The cathode electrode 173 may be formed of a transparent conductive oxide (TCO) such as ITO or indium zinc oxide (IZO), or a semi-transmissive conductive material such as Mg, Ag, or an alloy thereof. In case that the cathode electrode 173 is formed of a semi-transmissive conductive material, light emission efficiency may be enhanced by a microcavity effect.

The encapsulation layer ENC may be located on the light-emitting element layer EML. The encapsulation layer ENC may prevent oxygen or moisture from penetrating the light-emitting element layer EML. By way of example, the encapsulation layer ENC may protect the light-emitting element layer EML from foreign substances such as dust. The encapsulation layer ENC may include a first encapsulation layer TFE1, a second encapsulation layer TFE2, and a third encapsulation layer TFE3.

The first encapsulation layer TFE1 may be disposed on the cathode electrode 173, the second encapsulation layer TFE2 may be disposed on the first encapsulation layer TFE1, and the third encapsulation layer TFE3 may be disposed on the second encapsulation layer TFE2.

The first and third encapsulation layers TFE1 and TFE3 may be formed as multilayers in which one or more inorganic films, including one or more of silicon nitride, silicon oxynitride, silicon oxide, titanium oxide, and aluminum oxide, may be alternately stacked with each other.

The second encapsulation layer TFE2 may include an organic material. For example, the second encapsulation layer TFE2 may include a silicone resin, acrylic resin, silicone-acrylic resin, epoxy resin, phenolic resin, polyamide resin, or polyimide resin.

The resin layer RESIN may be located on the encapsulation layer ENC. The resin layer RESIN may completely cover the encapsulation layer ENC in the portions overlapping the emission areas EA and the non-emission area NLA.

The resin layer RESIN may be in contact with the encapsulation layer ENC through an optically clear adhesive film OCA. However, the optically clear adhesive film OCA may be omitted.

The polarizing film POL may be located on the resin layer RESIN. The polarizing film POL may be positioned on the display panel 100 to reduce external light reflection. The polarizing film POL may include a first base member, a linear polarizer, a quarter-wave plate (for example, a λ/4 plate) as a phase retardation film, and a second base member. The first base member, the phase retardation film, the linear polarizer, and the second base member of the polarizing film POL may be sequentially stacked on the display panel 100.

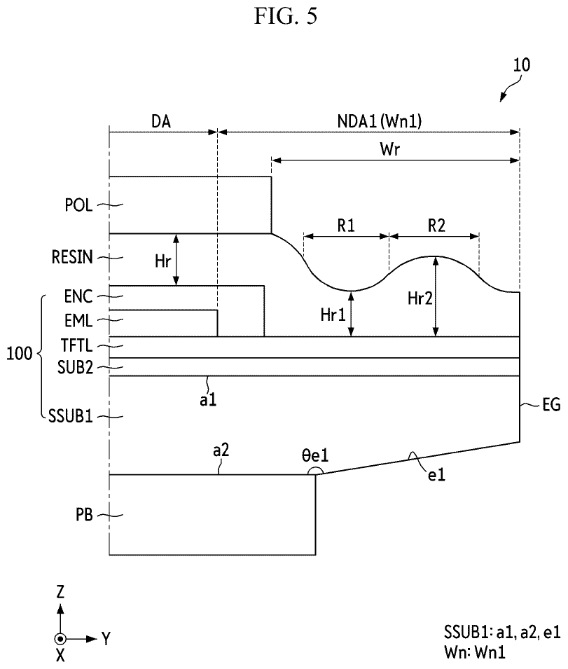

FIG. 5 is an enlarged schematic cross-sectional view of the display device 10 in the portion overlapping the first non-display area NDA1 in FIG. 2.

Referring to FIG. 5, the first sub-substrate SSUB1 may be located in the portion overlapping the first non-display area NDA1.

The first sub-substrate SSUB1 may include an edge surface e1 in the portion overlapping the first non-display area NDA1. The edge surface e1 may connect the second surface a2 and an outermost surface EG of the first sub-substrate SSUB1 in the portion overlapping the first non-display area NDA1.

The edge surface el may be an inclined surface. The edge surface el may be formed by etching a portion of the first sub-substrate SSUB 1 overlapping the first non-display area NDA1 during the manufacture of the display device 10. For example, an inclination angle θe1 formed by the second surface a2 and the edge surface e1 of the first sub-substrate SSUB1 may be an obtuse angle.

The second substrate SUB2 and the thin-film transistor layer TFTL may overlap the edge surface el of the first sub-substrate SSUB1 in the third direction (or the Z-axis direction). Further redundant descriptions may be omitted.

In an embodiment, the resin layer RESIN may completely fill the space between the display panel 100 and the polarizing film POL in the third direction (or the Z-axis direction). The polarizing film POL is illustrated as overlapping a portion of the first non-display area NDA1, but the disclosure is not limited thereto. In an embodiment, the polarizing film POL may entirely cover the resin layer RESIN in the portion overlapping the first non-display area NDA1.

In an embodiment, the resin layer RESIN may have an uneven thickness in the portion overlapping the first non-display area NDA1. By way of example, the resin layer RESIN may have at least one concave portion R1 and at least one convex portion R2 in the portion overlapping the first non-display area NDA1. The concave portion R1 may refer to a part of the surface of the resin layer RESIN that is indented toward the display panel 100, and the convex portion R2 may refer to a part of the surface of the resin layer RESIN that protrudes away from the display panel 100. The concave portion R1 and the convex portion R2 may not overlap the display area DA.

In an embodiment, the resin layer RESIN may have a minimum thickness Hr1 in a portion overlapping the concave portion R1 and a maximum thickness Hr2 in a portion overlapping the convex portion R2.

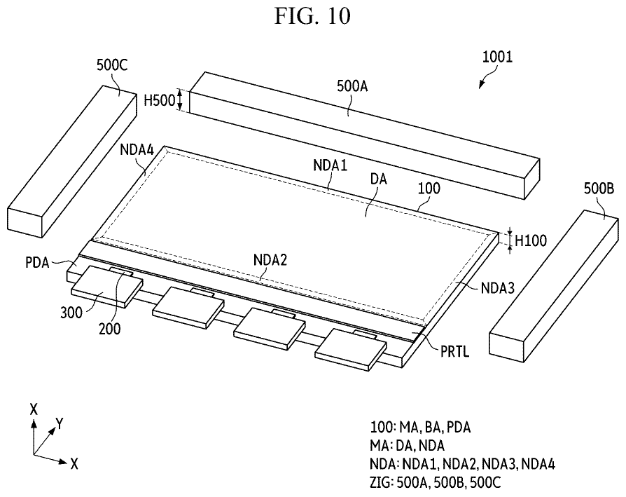

In an embodiment, during the manufacture of the display device 10, a resin application jig (“ZIG” in FIG. 10) may be placed in physical contact with an outermost surface EG of the display panel 100 adjacent to the first non-display area NDA1 to form the resin layer RESIN. Thus, in the portion overlapping the first non-display area NDA1, the resin layer RESIN may not form a gentle slope toward the outermost surface EG but may have at least one concave portion R1 and at least one convex portion R2. For example, in the portion overlapping the first non-display area NDA1, the resin layer RESIN may have a shape with its movement physically controlled. Consequently, the display device 10 can minimize a width Wr of the resin layer RESIN and can also minimize a width Wn1 of the first non-display area NDA1. The manufacturing process of the resin layer RESIN will be described later in detail.

As described above, the thickness Hr of the resin layer RESIN may be uniform in the portion overlapping the display area DA. Further redundant descriptions may be omitted.

In an embodiment, in the portion overlapping the first non-display area NDA1, the concave portion R1 and the convex portion R2 may overlap the edge surface e1 of the first sub-substrate SSUB1 in the third direction (or the Z-axis direction).

For convenience, the resin layer RESIN is illustrated and described as including one concave portion R1 and one convex portion R2 in the portion overlapping the first non-display area NDA1, but the disclosure is not limited thereto. As an example, the resin layer RESIN may include multiple concave portions R1 and multiple convex portions R2 in the portion overlapping the first non-display area NDA1. In this case, the multiple concave portions R1 may have different thicknesses, and the multiple convex portions R2 may also have different thicknesses.

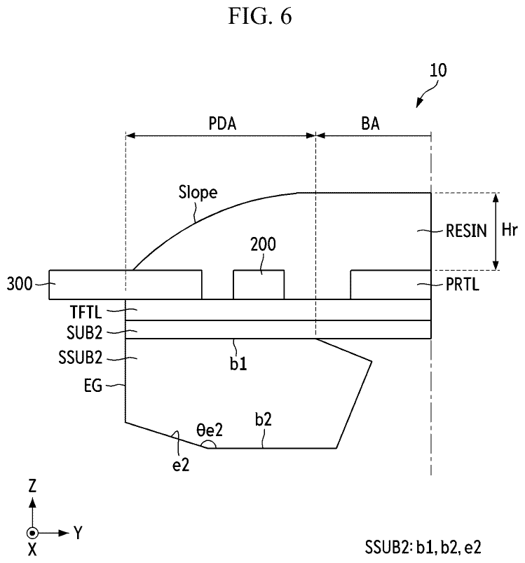

FIG. 6 is an enlarged schematic cross-sectional view of the display device 10 in the portion overlapping the pad area PDA in FIG. 2.

Referring to FIG. 6, the second sub-substrate SSUB2 may be located in the portion overlapping the pad area PDA. The second sub-substrate SSUB2 may include an edge surface e2 in the portion overlapping the pad area PDA. The edge surface e2 may connect the second surface b2 of the second sub-substrate SSUB2 to an outermost surface EG of the display panel 100 in the portion overlapping the pad area PDA.

The edge surface e2 may be an inclined surface. The edge surface e2 may be formed by etching a portion of the second sub-substrate SSUB2 overlapping the pad area PDA during the manufacture of the display device 10. For example, an inclination angle θe2 formed by the second surface b2 and the edge surface e2 of the second sub-substrate SSUB2 may be an obtuse angle.

In an embodiment, the second substrate SUB2, the thin-film transistor layer TFTL, and the circuit boards 300 may overlap the edge surface e2 of the second sub-substrate SSUB2 in the third direction (or the Z-axis direction). Further redundant descriptions may be omitted.

In an embodiment, the resin layer RESIN may be located on the display driving units 200 and the circuit boards 300 in the portion overlapping the pad area PDA. The resin layer RESIN may completely fill the space between the bending protection layer PRTL and the display driving units 200 in the second direction (or the Y-axis direction) and the space between the display driving units 200 and the circuit boards 300 in the second direction (or the Y-axis direction).

The resin layer RESIN may have an inclined surface in the portion overlapping the pad area PDA. In other words, the thickness Hr of the resin layer RESIN in the portion overlapping the pad area PDA may gradually decrease toward the outermost surface EG of the display panel 100.

In an embodiment, during the manufacture of the display device 10, the resin layer RESIN may be formed on the outermost surface EG of the display panel 100 adjacent to the pad area PDA, without using the resin application jig ZIG of FIG. 10. As a result, the resin layer RESIN may form a gentle slope toward the outermost surface EG in the portion overlapping the pad area PDA. For example, the shape of the resin layer RESIN in the portion overlapping the pad area PDA may differ from the shape of the resin layer RESIN in the portion overlapping the first non-display area NDA1, as described in FIG. 5. The manufacturing process of the resin layer RESIN will be described later in detail.

In an embodiment, the second substrate SUB2, the thin-film transistor layer TFTL, the display driving units 200, and the circuit boards 300 may overlap the slope included in the resin layer RESIN in the third direction (or the Z-axis direction).

In an embodiment, the slope included in the resin layer RESIN may overlap the edge surface e2 of the second sub-substrate SSUB2 in the third direction (or the Z-axis direction), but the disclosure is not limited thereto.

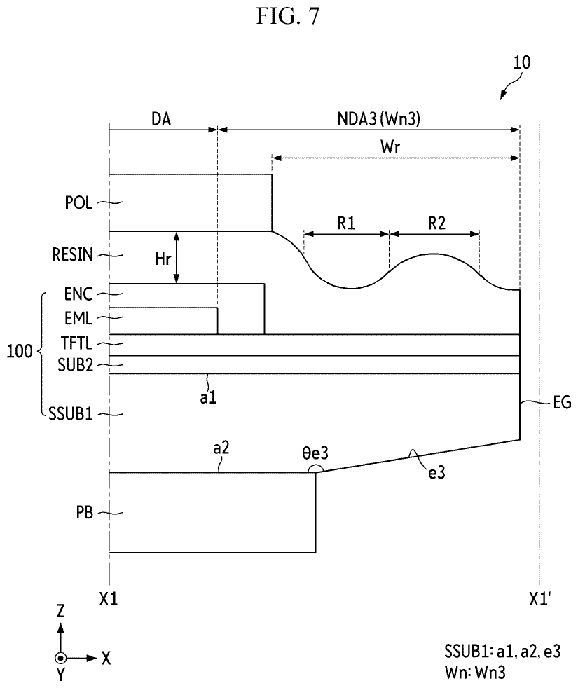

FIG. 7 is a schematic cross-sectional view taken along line X1-X1′ of FIG. 1. FIG. 7 is a schematic cross-sectional view of the display device 10 in a portion overlapping the third non-display area NDA3.

Referring to FIG. 7, the first sub-substrate SSUB1 may be located in the portion overlapping the third non-display area NDA3. The first sub-substrate SSUB1 may include an edge surface e3 in the portion overlapping the third non-display area NDA3. The edge surface e3 may connect the second surface a2 of the first sub-substrate SSUB1 to an outermost surface EG of the display panel 100 in the portion overlapping the third non-display area NDA3.

The edge surface e3 may be an inclined surface. The edge surface e3 may be formed by etching a portion of the first sub-substrate SSUB1 overlapping the third non-display area NDA3 during the manufacture of the display device 10. For example, an inclination angle θe3 formed by the second surface a2 and the edge surface e3 of the first sub-substrate SSUB1 may be an obtuse angle.

In an embodiment, the second substrate SUB2 and the thin-film transistor layer TFTL may overlap the edge surface e3 of the first sub-substrate SSUB1 in the third direction (or the Z-axis direction). Further redundant descriptions may be omitted.

The structure and features of the resin layer RESIN in the portion overlapping the display area DA have already been described, and thus, detailed descriptions thereof may be omitted.

In an embodiment, the resin layer RESIN may have an uneven thickness in the portion overlapping the third non-display area NDA3. By way of example, the resin layer RESIN may have at least one concave portion R1 and at least one convex portion R2 in the portion overlapping the third non-display area NDA3. The features of the concave portion R1 and the convex portion R2 overlapping the third non-display area NDA3 may be the same as those of the concave portion R1 and the convex portion R2 overlapping the first non-display area NDA1. Further redundant descriptions may be omitted.

In an embodiment, during the manufacture of the display device 10, the resin application jig ZIG of FIG. 10 may be placed in physical contact with the outermost surface EG of the display panel 100 adjacent to the third non-display area NDA3 to form the resin layer RESIN. Thus, in the portion overlapping the third non-display area NDA3, the resin layer RESIN may not form a gentle slope toward the outermost surface EG but may have at least one concave portion R1 and at least one convex portion R2. For example, in the portion overlapping the third non-display area NDA3, the resin layer RESIN may have a shape with its movement physically controlled. The manufacturing process of the resin layer RESIN will be described later in detail.

In an embodiment, by using the resin application jig ZIG of FIG. 10 during the manufacture of the display device 10, the width Wr of the resin layer RESIN having uneven thicknesses Hr1 and Hr2 in the portion overlapping the third non-display area NDA3 can be minimized. Thus, a width Wn3 of the third non-display area NDA3 can also be minimized.

In an embodiment, in the portion overlapping the third non-display area NDA3, the concave portion R1 and the convex portion R2 may overlap the edge surface e3 of the first sub-substrate SSUB1 in the third direction (or the Z-axis direction).

In an embodiment, the resin layer RESIN may have multiple concave portions R1 and multiple convex portions R2 in the portion overlapping the third non-display area NDA3. Further redundant descriptions may be omitted.

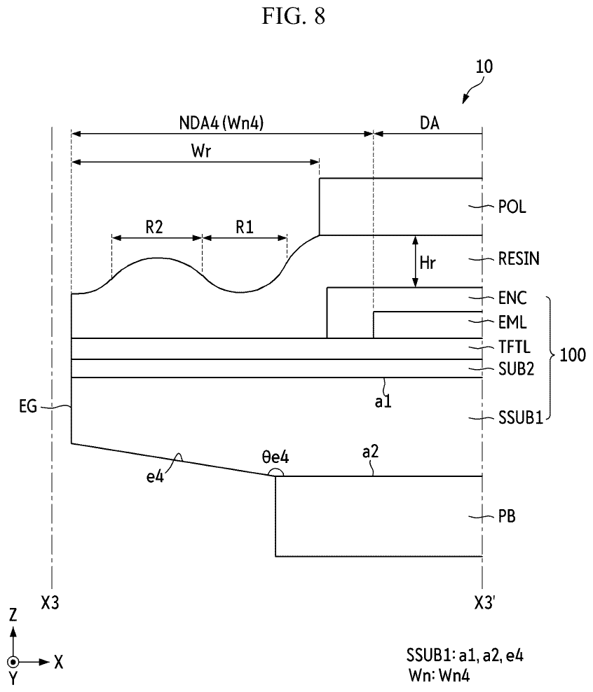

FIG. 8 is a schematic cross-sectional view taken along line X3-X3′ of FIG. 1.

Referring to FIG. 8, the first sub-substrate SSUB 1 may be located in a portion overlapping the fourth non-display area NDA4. The first sub-substrate SSUB1 may include an edge surface e4 in the portion overlapping the fourth non-display area NDA4. The edge surface e4 may connect the second surface a2 of the first sub-substrate SSUB1 to an outermost surface EG of the display panel 100 in the portion overlapping the fourth non-display area NDA4.

The edge surface e4 may be an inclined surface. The edge surface e4 may be formed by etching a portion of the first sub-substrate SSUB1 overlapping the fourth non-display area NDA4 during the manufacture of the display device 10. For example, an inclination angle θe4 formed by the second surface a2 and the edge surface e4 of the first sub-substrate SSUB1 may be an obtuse angle.

In an embodiment, the second substrate SUB2 and the thin-film transistor layer TFTL may overlap the edge surface e4 of the first sub-substrate SSUB1 in the third direction (or the Z-axis direction). Further redundant descriptions may be omitted.

The structure and features of the resin layer RESIN in the portion overlapping the display area DA have already been described, and thus, detailed descriptions thereof may be omitted.

In an embodiment, the resin layer RESIN may have an uneven thickness in the portion overlapping the fourth non-display area NDA4. By way of example, the resin layer RESIN may have at least one concave portion R1 and at least one convex portion R2 in the portion overlapping the fourth non-display area NDA4. The features of the concave portion R1 and the convex portion R2 overlapping the fourth non-display area NDA4 may be the same as those of the concave portion R1 and the convex portion R2 overlapping the first non-display area NDA1. Further redundant descriptions may be omitted.

In an embodiment, during the manufacture of the display device 10, the resin application jig ZIG of FIG. 10 may be placed in physical contact with the outermost surface EG of the display panel 100 adjacent to the fourth non-display area NDA4 to form the resin layer RESIN. Thus, in the portion overlapping the fourth non-display area NDA4, the resin layer RESIN may not form a gentle slope toward the outermost surface EG but may have at least one concave portion R1 and at least one convex portion R2. For example, in the portion overlapping the fourth non-display area NDA4, the resin layer RESIN may have a shape with its movement physically controlled. The manufacturing process of the resin layer RESIN will be described later in detail.

In an embodiment, by using the resin application jig ZIG of FIG. 10 during the manufacture of the display device 10, the width Wr of the resin layer RESIN having uneven thicknesses Hr1 and Hr2 in the portion overlapping the fourth non-display area NDA4 can be minimized. Thus, a width Wn4 of the fourth non-display area NDA4 can also be minimized.

In an embodiment, in the portion overlapping the fourth non-display area NDA4, the concave portion R1 and the convex portion R2 may overlap the edge surface e4 of the first sub-substrate SSUB1 in the third direction (or the Z-axis direction).

In an embodiment, the resin layer RESIN may have multiple concave portions R1 and multiple convex portions R2 in the portion overlapping the fourth non-display area NDA4. Further redundant descriptions may be omitted.

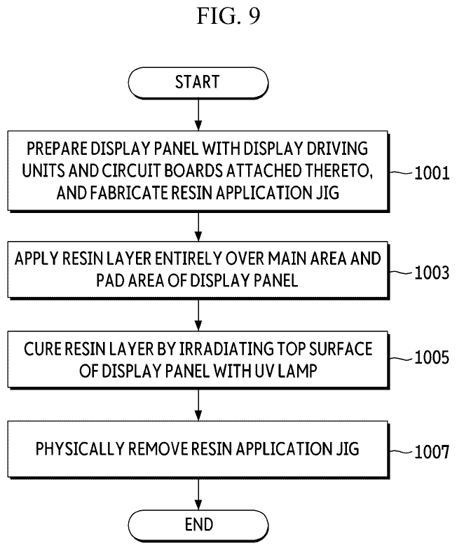

FIG. 9 is a flowchart illustrating a method of manufacturing a resin layer according to an embodiment. FIGS. 10 through 16 are process perspective views and plan views for explaining the method of manufacturing a resin layer according to an embodiment.

The method of manufacturing a resin layer according to an embodiment will hereinafter be described with reference to FIGS. 9 through 16. The following description represents only part of the manufacturing process of a resin layer, and additional steps for forming the components described in the disclosure may be performed before or after each step of the method of manufacturing a resin layer according to an embodiment. Furthermore, manufacturing procedures to those skilled in the art may be additionally performed before or after each step of the method of manufacturing a resin layer according to an embodiment.

Referring to FIG. 9, in step 1001, a display panel with display driving units and circuit boards attached thereto may be prepared, and a resin application jig may be fabricated.

By way of example, referring to FIGS. 10 through 12, a display panel 100 with display driving units 200 and circuit boards 300 attached thereto is prepared. The display panel 100 may include a main area MA, a bending area BA, and a pad area PDA, and the main area MA may include a display area DA and a non-display area NDA. By way of example, the non-display area NDA may include first through fourth non-display areas NDA1 through NDA4. The display driving units 200 and circuit boards 300 may be located on the pad area PDA of the display panel 100. Further redundant descriptions may be omitted.

Thereafter, a resin application jig ZIG suitable for the size of the display panel 100 is fabricated. In this process, the resin application jig ZIG may be fabricated to contact outermost surfaces EG of the display panel 100. Therefore, the resin application jig ZIG may surround some of the outermost surfaces EG of the display panel 100 and may fix the display panel 100 in place. The resin application jig ZIG may not be attached to the display panel 100 using an adhesive but may be placed in physical contact with the display panel 100.

On a plane, the resin application jig ZIG may be positioned to entirely surround the main area MA. The resin application jig ZIG may also surround the bending area BA, but the disclosure is not limited thereto. On a plane, the resin application jig ZIG may not be located on one side or a side of the pad area PDA overlapping the circuit boards 300.

The resin application jig ZIG may be composed of release blocks 500, or a single integral release block 500. The release block(s) 500 may have a rectangular parallelepiped shape, but the disclosure is not limited thereto. The release block(s) 500 may include both organic and inorganic materials. For example, the release block(s) 500 may be formed of silicone.

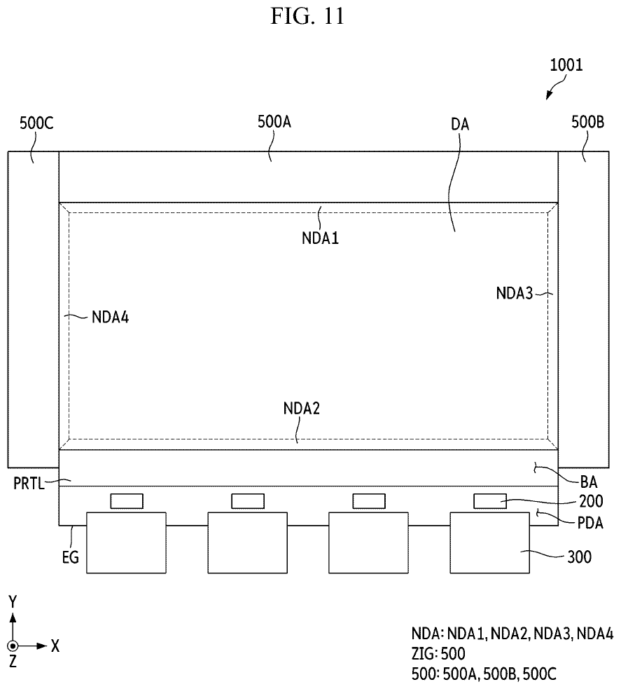

In an embodiment, as illustrated in FIGS. 10 and 11, in case that a resin application jig ZIG is formed using release blocks 500, the release blocks 500 may include a first release block 500A, a second release block 500B, and a third release block 500C. By way of example, the first release block 500A may be positioned in contact with the outermost surface EG overlapping the first non-display area NDA1, the second release block 500B may be positioned in contact with the outermost surface EG overlapping the third non-display area NDA3, and the third release block 500C may be positioned in contact with the outermost surface EG overlapping the fourth non-display area NDA4.

The first, second, and third release blocks 500A, 500B, and 500C may have the same thickness, for example, a thickness H500. The sizes of the release blocks 500 in the first direction (or the X-axis direction) and the second direction (or the Y-axis direction) may be adjusted according to the size of the display panel 100. The thickness H500 of the release blocks 500 may be greater than a thickness H100 of the display panel 100. Consequently, the resin application jig ZIG may physically control a resin layer RESIN not to overflow the outermost surfaces EG of the display panel 100 in case that formed on the display panel 100. This will be described later in further detail.

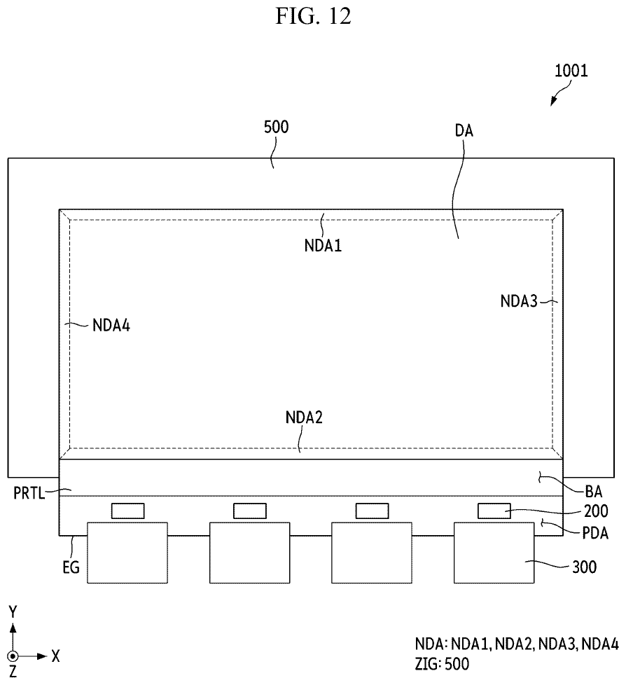

In an embodiment, as illustrated in FIG. 12, in case that a single integral release block 500 is formed, the release block 500 may entirely surround the main area MA of the display panel 100 and may be integrally formed, exposing the pad area PDA overlapping the circuit boards 300.

Thereafter, referring again to FIG. 9, in step 1003, a resin layer is applied over the main area and the pad area of the display panel.

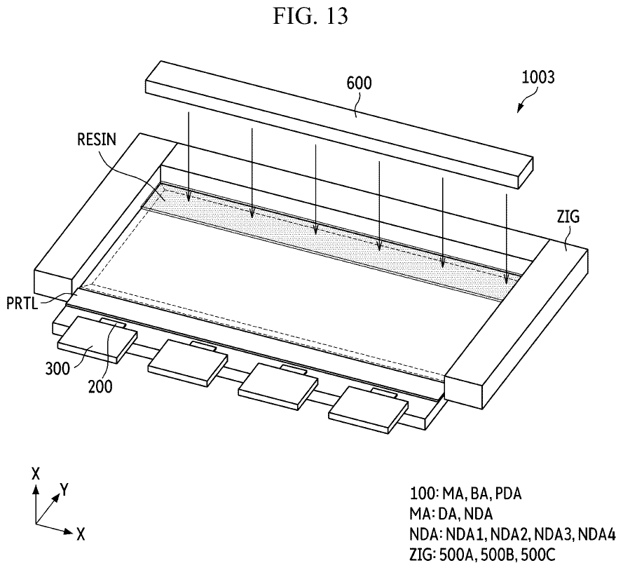

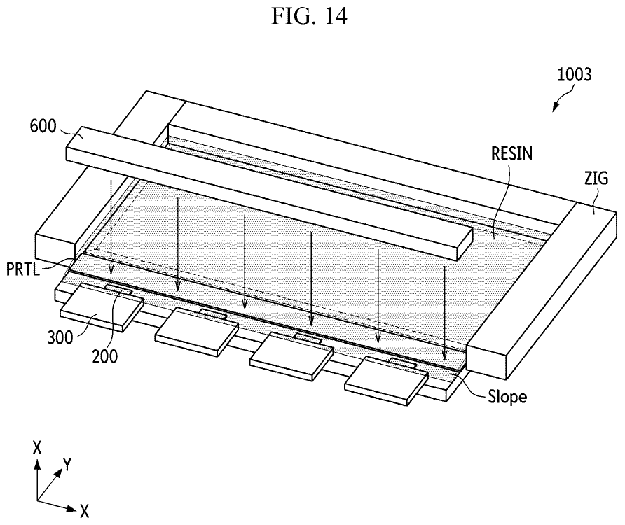

By way of example, referring to FIGS. 13 and 14, the resin layer RESIN may be applied using a resin application device 600. The resin application device 600 may include equipment capable of applying an organic material. For example, the resin application device 600 may be a dispensing device, a screen printing device, an inkjet printing device, or a slit die. The material of the resin layer RESIN has already been described, and thus, a description thereof may be omitted.

For convenience, the resin application device 600 is illustrated as applying resin in the second direction (or the Y-axis direction), but the disclosure is not limited thereto. The resin application device 600 may also apply resin in the first direction (or the X-axis direction).

In this process, the resin application jig ZIG may physically control the overflow of the resin layer RESIN. Thus, the resin layer RESIN may be applied to the desired area without overflowing beyond the display panel 100.

The resin layer RESIN may be applied to overlap the main area MA, the bending area BA, and the pad area PDA. The resin layer RESIN may be integrally formed, overlapping the main area MA, the bending area BA, and the pad area PDA. In other words, the resin layer RESIN, overlapping the main area MA, the bending area BA, and the pad area PDA, may be formed as a single layer without separate boundaries.

In this process, the resin layer RESIN may contact and cover the display panel 100, a bending protection layer PRTL, the display driving units 200, and the circuit boards 300.

In this process, in portions overlapping the first non-display area NDA1, the third non-display area NDA3, and the fourth non-display area NDA4, the resin layer RESIN may be physically controlled by the resin application jig ZIG. Thus, as illustrated in FIG. 5, the resin layer RESIN may include at least one concave portion R1 and at least one convex portion R2 in the portion overlapping the first non-display area NDA1. By way of example, the resin layer RESIN may be formed as illustrated in FIG. 7 in the portion overlapping the third non-display area NDA3, and may be formed as illustrated in FIG. 8 in the portion overlapping the fourth non-display area NDA4.

As described above, the flow of the resin layer RESIN in the portions overlapping the first non-display area NDA1, the third non-display area NDA3, and the fourth non-display area NDA4 can be controlled using the resin application jig ZIG. In this manner, the width (“Wn” in FIGS. 5, 7, and 8) of the non-display area NDA can be minimized. Here, the term “width” may be used interchangeably with “area” or “breadth.” Therefore, a display device 10 can have a maximized display area DA. Further redundant descriptions may be omitted.

In this process, in a portion overlapping the circuit boards 300, the resin layer RESIN is not physically controlled by the resin application jig ZIG and may thus include a slope, as illustrated in FIG. 6. Further redundant descriptions may be omitted.

Referring again to FIG. 9, in step 1005, the resin layer is cured by irradiating the top surface of the display panel with an ultraviolet (UV) lamp, and in step 1007, the resin application jig is physically removed.

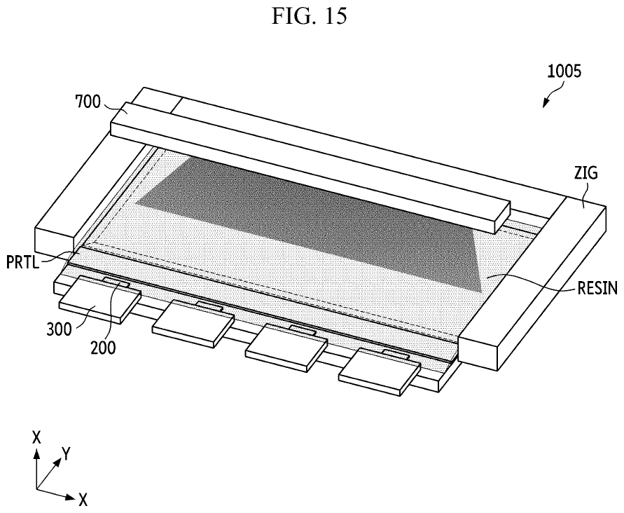

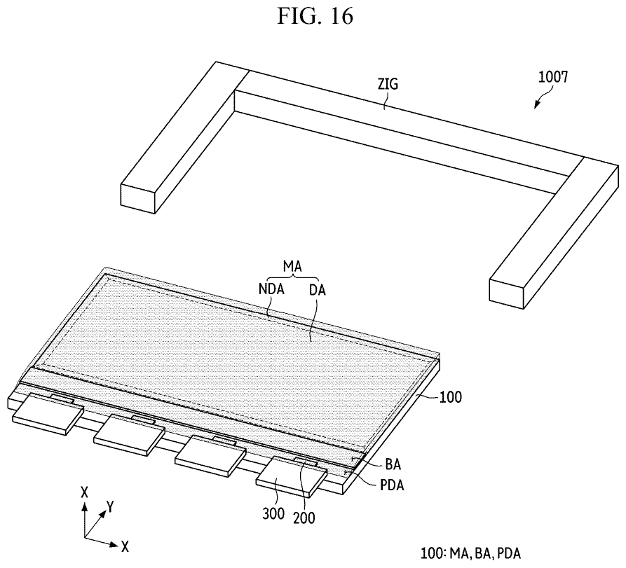

By way of example, referring to FIGS. 15 and 16, the resin layer RESIN may be cured using a UV lamp 700. The UV lamp 700, which is of a bar type, may sweep across the entire resin layer RESIN. The UV lamp 700 may be a lamp capable of irradiating UV light using light-emitting diode (LED) chips of about 365 nm, about 385 nm, about 395 nm, about 405 nm, etc. The resin layer RESIN, which is integrally formed, may be cured simultaneously in its entirety.

Thereafter, the resin application jig ZIG is physically separated from the display panel 100. The resin application jig ZIG may be readily separated without the need for additional equipment.

In an embodiment, the resin layer RESIN may be formed as an integral layer overlapping the main area MA, the bending area BA, and the pad area PDA through a single process. Therefore, the display device 10 can be readily manufactured.

In this manner, the resin layer RESIN of the display device 10 may be formed. Since the display device 10 may include the resin layer RESIN covering not only the display panel 100, but also the display driving units 200 and circuit boards 300 overlapping the pad area PDA, the mechanical strength of the display panel 100, the display driving units 200, and the circuit boards 300 can be enhanced.

The display device according to an embodiment of the disclosure can be applied to various electronic devices. The electronic device according to an embodiment of the disclosure includes the display device described above, and may further include modules or devices having additional functions in addition to the display device.

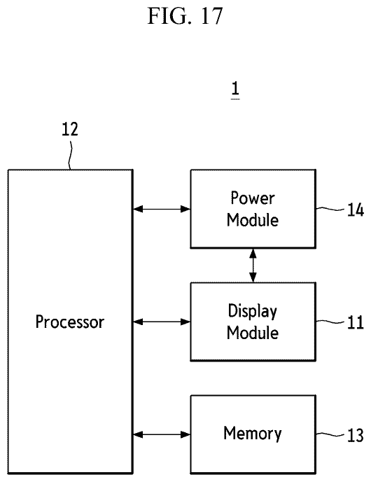

FIG. 17 is a block diagram of an electronic device according to an embodiment of the disclosure.

Referring to FIG. 17, the electronic device 1 according to an embodiment of the disclosure may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), and a controller.

The memory 15 may store data information necessary for the operation of the processor 12 or the display module 11. When the processor 12 executes an application stored in the memory 15, an image data signal and/or an input control signal is transmitted to the display module 11, and the display module 11 can process the received signal and output image information through a display screen.

The power module 14 may include a power supply module such as, for example a power adapter or a battery, and a power conversion module that converts the power supplied by the power supply module to generate power necessary for the operation of the electronic device 1.

At least one of the components of the electronic device 11 according to an embodiment of the disclosure may be included in the display device 10 according to the embodiments of the disclosure. In addition, some modules of the individual modules functionally included in one module may be included in the display device 10, and other modules may be provided separately from the display device 10. For example, the display device 10 may include the display module 11, and the processor 12, the memory 13, and the power module 14 may be provided in the form of other devices within the electronic device 11 other than the display device 10.

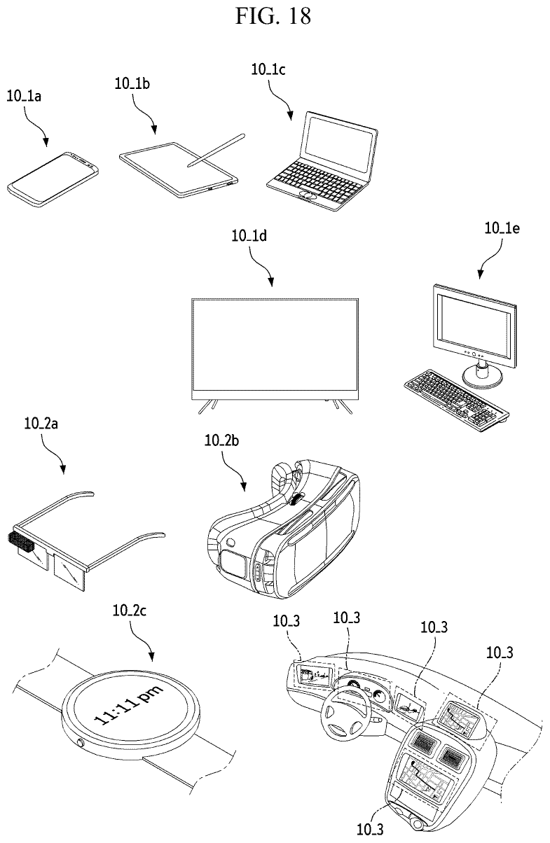

FIG. 18 is a schematic diagram of an electronic device according to various embodiments of the disclosure.

Referring to FIG. 18, various electronic devices to which display devices 10 according to embodiments of the disclosure are applied may include not only image display electronic devices such as a smart phone 10_1a, a tablet PC (personal computer) 10_1b, a laptop 10_1c, a TV 10_1d, and a desk monitor 10_1e, but also wearable electronic devices including display modules such as, for example smart glasses 10_2a, a head mounted display 10_2b, and a smart watch 10_2c, and vehicle electronic devices 10_3 including display modules such as a CID (Center Information Display) and a room mirror display arranged on a dashboard, center fascia, and dashboard of an automobile.

Embodiments have been disclosed herein, and although terms are employed, they are used and are to be interpreted in a generic and descriptive sense only and not for purpose of limitation. In some instances, as would be apparent by one of ordinary skill in the art, features, characteristics, and/or elements described in connection with an embodiment may be used singly or in combination with features, characteristics, and/or elements described in connection with other embodiments unless otherwise indicated. Accordingly, it will be understood by those of ordinary skill in the art that various changes in form and details may be made without departing from the spirit and scope of the disclosure and as set forth in the following claims.

What is claimed is:

1. A display device comprising:
a display panel including a main area, a bending area, and a pad area;
a display driver and a circuit board disposed on the pad area of the display panel;
a resin layer disposed on the display panel and covering the display driver and the circuit board; and
a polarizing film disposed on the resin layer,
wherein the resin layer is formed in portions overlapping the main area, the bending area, and the pad area.

2. The display device of claim 1, wherein
in a portion overlapping the main area, the resin layer contacts the display panel and the polarizing film, and
the resin layer completely fills a space between the display panel and the polarizing film in a direction perpendicular to the display panel.

3. The display device of claim 2, wherein the resin layer contacts the display driver and the circuit board, and completely covers the display driver.

4. The display device of claim 3, wherein the resin layer includes an organic material.

5. The display device of claim 1, wherein
the main area includes a display area and a non-display area surrounding the display area, and
a shape of the resin layer overlapping the non-display area differs from a shape of the resin layer overlapping the pad area in a cross-section.

6. The display device of claim 5, wherein the resin layer includes at least one concave portion and at least one convex portion, which have different thicknesses, in a portion overlapping the non-display area in the cross-section.

7. The display device of claim 6, wherein
the concave portion is a portion that includes a minimum thickness of the resin layer relative to the display panel, and
the convex portion is a portion that includes a maximum thickness of the resin layer relative to the display panel.

8. The display device of claim 5, wherein in a portion overlapping the pad area, the resin layer includes a slope with a thickness that gradually decreases in a direction toward an outermost surface of the display panel.

9. The display device of claim 8, wherein the slope of the resin layer overlaps the display driver and the circuit board in a direction perpendicular to the display panel.

10. The display device of claim 5, wherein the resin layer includes a uniform thickness in a portion overlapping the display area, with a process tolerance of about 50 μm.

11. The display device of claim 5, wherein
the display panel includes a first substrate, overlapping the main area and the pad area, and including an opening overlapping the bending area, and having a rigid material, and a second substrate, disposed on the first substrate and having a flexible material,
the first substrate includes a first sub-substrate, overlapping the main area, and a second sub-substrate, overlapping the pad area, and
the first substrate and the second sub-substrate are spaced apart with the opening disposed between the first substrate and the second sub-substrate.

12. The display device of claim 11, wherein
the first sub-substrate includes a first surface facing the second substrate, a second surface opposite to the first surface, and an edge surface connecting the second surface and an outermost surface of the display panel in a portion overlapping the non-display area, and
an inclination angle formed by the second surface and the edge surface is an obtuse angle.

13. The display device of claim 12, wherein in a direction perpendicular to the display panel, the edge surface overlaps the resin layer.

14. The display device of claim 12, wherein
the first sub-substrate further includes a first side surface connected to the first surface and facing the bending area, and a second side surface connected to the first side surface and the second surface and facing the bending area,
the first side surface of the first sub-substrate and a lower surface of the second substrate form an undercut in a direction toward the bending area, and
the resin layer overlaps the undercut in a direction perpendicular to the display panel.

15. The display device of claim 14, wherein
the second sub-substrate includes a third side surface facing the bending area and opposite to the first side surface of the first sub-substrate,
the third side surface and the second substrate form the undercut in a direction toward the bending area; and
in a direction perpendicular to the display panel, the resin layer overlaps the third side surface.

16. A method of manufacturing a display device, comprising:
preparing a display panel including a main area, a bending area, and a pad area, and a display driver and circuit board attached to the pad area of the display panel;
attaching a resin application jig, which entirely surrounds the main area, to an outermost surface of the display panel;
applying a resin layer over the main area, bending area, and pad area of the display panel and curing the resin layer with an ultraviolet (UV) lamp; and removing the resin application jig.

17. The method of claim 16, wherein in a forming of the resin layer, the resin layer is formed in portions overlapping the main area, bending area, and the pad area.

18. The method of claim 17, wherein in the forming of the resin layer, a flow of the resin layer overlapping a non-display area is controlled by the resin application jig.

19. The method of claim 16, wherein in the attaching of the resin application jig, the resin application jig does not overlap the circuit board.

20. The method of claim 19, wherein
in a forming of the resin layer, the resin layer overlapping a non-display area includes at least one concave portion and at least one convex portion, and
the resin layer overlapping the pad area includes a slope with a thickness decreasing toward the outermost surface of the display panel.

21. An electronic device comprising:
a display device comprising:
a display panel including a main area, a bending area, and a pad area;
a display driver and a circuit board disposed on the pad area of the display panel;
a resin layer disposed on the display panel and covering the display driver and the circuit board; and
a polarizing film disposed on the resin layer,
wherein the resin layer is formed in portions overlapping the main area, the bending area, and the pad area.
